(19) United States
(12) Patent Application Publication
(10) Pub. No.: US 2009/0294793 A1
(43) Pub. Date: Dec. 3, 2009

(54) LED PACKAGE AND METHOD OF MANUFACTURING THE SAME

(75) Inventors: Dae Yeon KIM, Suwon (KR); Hun Joo HAHM, Seongnam (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/164,685

(22) Filed: Jun. 30, 2008

(30) Foreign Application Priority Data
May 29, 2008 (KR) 10-2008-0050050

(51) Int. Cl. H01L 33/00; H01L 21/00

(52) U.S. Cl. 257/99; 438/26; 257/E33.001

(57) ABSTRACT

Provided is an LED package including a heat radiating portion that is composed of two or more metal layers and has a cavity formed therein; a first lead that extends from one side of the heat radiating portion; a second lead that is formed in the other side of the heat radiating portion so as to be separated from the heat radiating portion; a mold portion that fixes the heat radiating portion and the first and second leads; an LED chip that is mounted in the cavity; and a first filler that is filled in the cavity so as to protect the LED chip.

### CROSS-REFERENCE TO RELATED APPLICATIONS

This application claims the benefit of Korean Patent Application No. 10-2008-0050050 filed with the Korea Intellectual Property Office on May 29, 2008, the disclosure of which is incorporated herein by reference.

### BACKGROUND OF THE INVENTION

1. Field of the Invention

The present invention relates to a light emitting diode (LED) package and a method of manufacturing the same.

2. Description of the Related Art

In general, LED is a light emitting device which emits light when a current flows and is a PN junction diode composed of GaAs or GaN semiconductor, which converts electric energy into light energy.

The range of light emitted from the LED includes red (630-700 nm), blue-violet (400 nm), blue, green, and white lights. Compared with existing light sources such as an incandescent lamp and a fluorescent lamp, the LED has low power consumption and a long lifespan and exhibits high efficiency. Therefore, demand for the LED is continuously increasing.

Recently, the application of the LED is expanded into small lighting devices for mobile terminals, vehicle lighting devices, backlights for large-sized LCD (Liquid Crystal Display) and so on.

When the LED is applied as a backlight, the optical orientation angle of light emitted from an LED package should be secured, in order to reduce an optical thickness. To implement the optical orientation angle while minimizing the size of the LED package, the size of a light source should be minimized.

When the LED is applied as a lighting device, a lens for high emission efficiency should be used. When the size of a light source is large, a color coordinate/color temperature characteristic may differ. To overcome such a problem, the size of the light source should be minimized.

Conventionally, in order to reduce the size of a light source, a micro cavity is formed in a mold portion formed of resin, and an LED chip is mounted in the cavity. In this case, when the surface of the mold portion is exposed to a high-temperature and high-power environment for a long time, the surface may be discolored. As a result, the brightness of the LED package decreases, and the lifespan thereof is reduced. Such a problem frequently occurs as the size of the cavity decreases.

### SUMMARY OF THE INVENTION

An advantage of the present invention is that it provides an LED package in which a cavity is formed in a heat radiating portion composed of two or more metal layers and an LED chip is mounted in the cavity such that a mold portion is prevented from being discolored, thereby enhancing the reliability of the LED package and reducing the size of a light source.

Another advantage of the invention is that it provides a method of manufacturing an LED package.

Additional aspects and advantages of the present general inventive concept will be set forth in part in the description which follows and, in part, will be obvious from the description, or may be learned by practice of the general inventive concept.

According to an aspect of the invention, an LED package comprises a heat radiating portion that is composed of two or more metal layers and has a cavity formed therein; a first lead that extends from one side of the heat radiating portion; a second lead that is formed in the other side of the heat radiating portion so as to be separated from the heat radiating portion; a mold portion that fixes the heat radiating portion and the first and second leads; an LED chip that is mounted in the cavity; and a first filler that is filled in the cavity so as to protect the LED chip.

The heat radiating portion may be formed of one metal plate which is folded in such a manner that two or more metal layers are provided.

When the heat radiating portion is composed of two metal layers, the cavity may be formed in the upper metal layer of the heat radiating portion.

When the heat radiating portion is composed of three or more metal layers, the cavity may be formed in a plurality of metal layers such that the top surface of the lowermost metal layer of the heat radiating portion is exposed through the cavity.

When the heat radiating portion is composed of three or more metal layers, the cavity may be formed in such a manner that the top surface of two or more metal layers including the lowermost metal layer of the heat radiating portion are exposed through the cavity.

The inner surface of the cavity may be formed of an inclined surface.

The LED package may further comprise a wire that connects the LED chip and the second lead.

The mold portion may have an opening portion larger than the cavity.

The LED package may further comprise a second filler that is filled into the opening portion.

The LED package may further comprise a lens that is coupled to the top surface of the mold portion.

Further, a reflecting member composed of Ag may be formed on the surfaces of the heat radiating portion including the cavity and the first and second leads.

According to another aspect of the invention, a method of manufacturing an LED package comprises providing a heat radiating portion having a first lead extending from one side of the heat radiating portion and a second lead formed in the other side of the heat radiating portion so as to be separated from the heat radiating portion; forming a cavity in a portion of the heat radiating portion; folding the heat radiating portion into two or more metal layers such that the portion in which the cavity is formed is positioned in the uppermost layer; forming a mold portion which fixes the heat radiating portion and the first and second leads; mounting an LED chip in the cavity; connecting the LED chip to the second lead through wire bonding; and filling the cavity with a first filler.

In the forming of the cavity, the inner surface of the cavity may be formed of an inclined surface.

In the forming of the mold portion, an opening portion larger than the cavity may be formed in the mold portion.

The method may further comprise filling the opening portion with a second filler, after the filling of the cavity.

The method may further comprise coupling a lens to the top surface of the mold portion, after the filling of the opening portion.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of an LED package according to an embodiment of the invention;

FIG. 2A is a development diagram of a heat radiating portion of the LED package according to the embodiment of the invention;

FIG. 2B is a perspective view of the heat radiating portion of the LED package of FIG. 2A;

FIG. 3A is a development diagram of a heat radiating portion of an LED package according to another embodiment of the invention;

FIG. 3B is a perspective view of the heat radiating portion of the LED package of FIG. 3A; and

FIGS. 4 and 10 are process diagrams sequentially showing a method of manufacturing an LED package according to an embodiment of the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, an LED package and a method of manufacturing the same according to the present invention will be described in detail with reference to the accompanying drawings.

Structure of LED Package

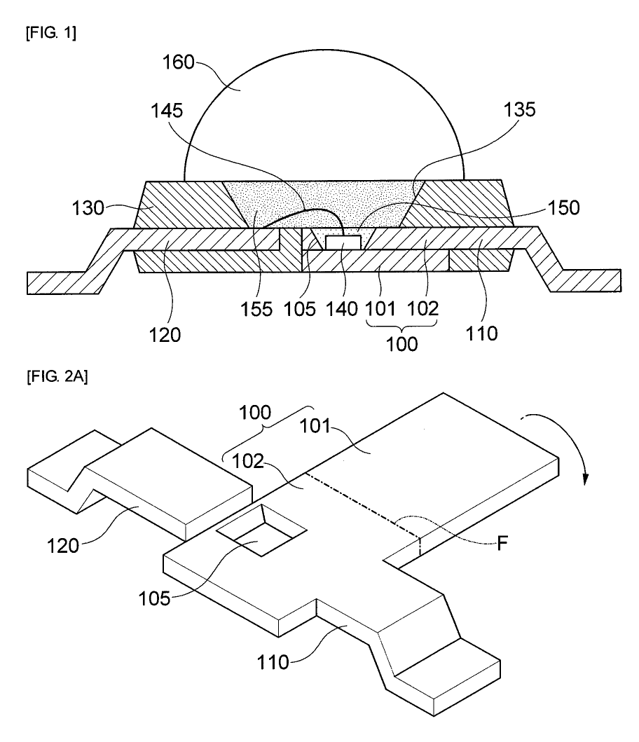

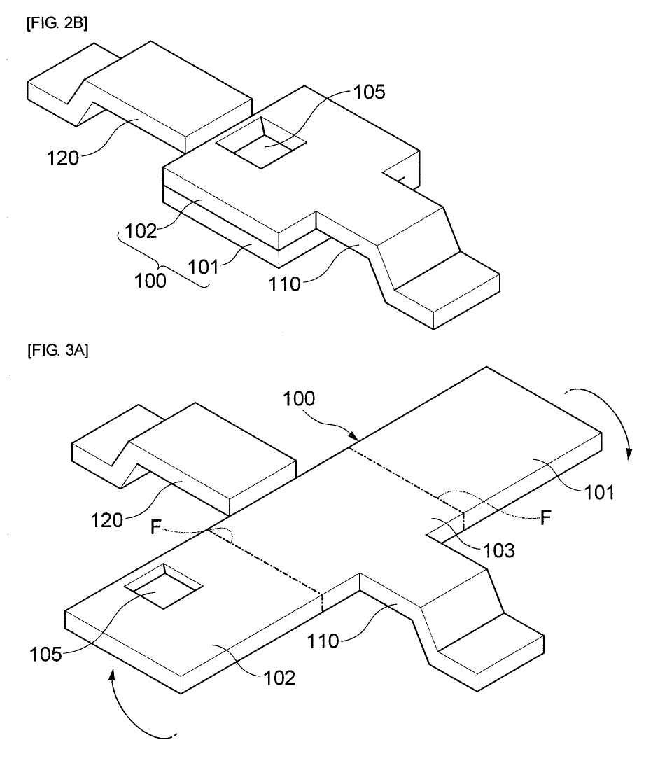

Referring to FIGS. 1 and 2, an LED package according to an embodiment of the invention will be described.

FIG. 1 is a cross-sectional view of an LED package according to an embodiment of the invention. FIG. 2A is a development diagram of a heat radiating portion of the LED package according to the embodiment of the invention. FIG. 2B is a perspective view of the heat radiating portion of the LED package of FIG. 2A.

As shown in FIG. 1, the LED package according to the embodiment of the invention includes a heat radiating portion 100 having a cavity 105 formed therein, a first lead 110 extending from one side of the heat radiating portion 100, a second lead 120 which is formed in the other side of the heat radiating portion 100 so as to be separated from the heat radiating section 100, a mold portion 130 which fixes the heat radiating section 100 and the first and second leads 110 and 120, and an LED chip 140 mounted in the cavity 105.

The LED chip 140 and the second lead 120 can be electrically connected through wire bonding.

The cavity 105 is filled with a first filler 150 for protecting the LED chip 140. The first filler 150 may be composed of optically-transparent resin, such as silicon resin or epoxy resin.

The first filler 150 may contain one or more kinds of phosphors such that light emitted from a light source provided in a backlight unit is converted into white light. In this case, red, green, or blue light emitted from the LED chip 140, depending on the material forming the LED chip 140, may be converted into white light by the phosphors contained in the filler 150 so as to be emitted from the package.

The mold portion 130 may be formed of resin.

The mold portion 130 has an opening portion 135 provided therein, through which light emitted from the LED chip 140 can be extracted to the outside. Preferably, the opening portion 135 is set to be larger than the cavity 105.

Inside the opening portion 135 of the mold portion 130, a second filler 155 may be filled. The second filler 155 may be formed of optically-transparent resin such as silicon resin or epoxy resin.

On the top surface of the mold portion 130, a lens 160 is coupled, which extracts light emitted from the LED chip 140 to the outside at a wide orientation angle.

In the LED package according to the embodiment of the invention, the heat radiating portion 100 may be composed of two metal layers 101 and 102. In this case, the heat radiating portion 100 may be formed of one metal plate which is folded in such a manner that two metal layers 101 and 102 are provided.

As shown in FIGS. 2A and 2B, when the heat radiating portion 100 is composed of two metal layers 101 and 102, the heat radiating portion 100 may be folded along line F such that the bottom surface of the upper metal layer 102 comes in contact with the top surface of the lower metal layer 101. In this case, the cavity 105 in which the LED chip 140 is mounted may be formed in the upper metal layer 102 of the heat radiating portion 100.

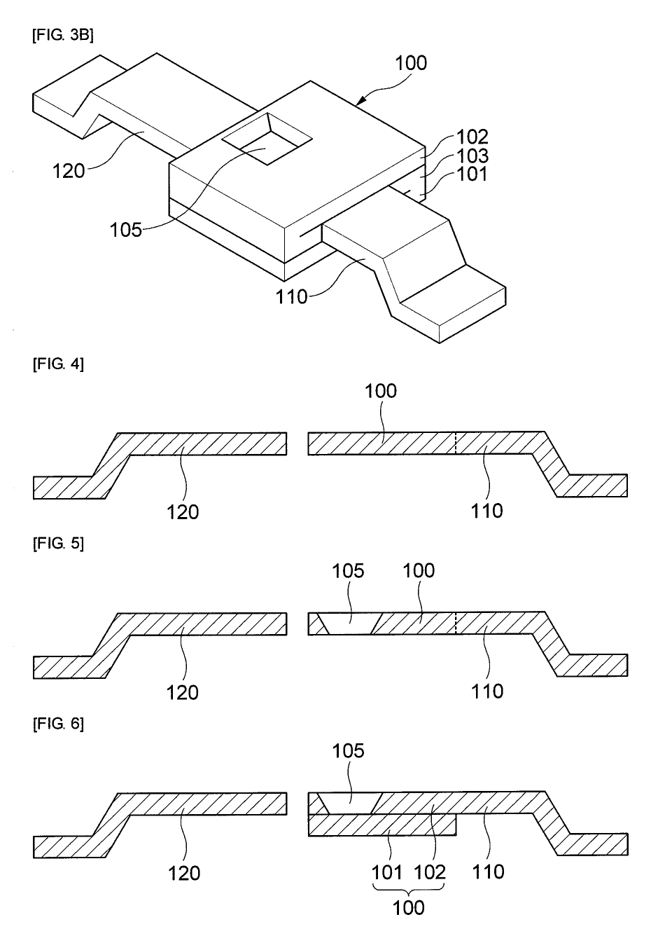

FIG. 3A is a development diagram of a heat radiating portion of an LED package according to another embodiment of the invention. FIG. 3B is a perspective view of the heat radiating portion of the LED package of FIG. 3A.

As shown in FIGS. 3A and 3B, when the heat radiating portion 100 is composed of three metal layers, the heat radiating portion 100 may be folded along lines F such that the bottom surface of the upper metal layer 102 comes in contact with the top surface of the intermediate metal layer 103 and the top surface of the lower metal layer 101 comes in contact with the bottom surface of the intermediate metal layer 103.

As such, when the heat radiating portion 100 is composed of three metal layers, the cavity 105 may be formed in only the upper metal layer 102 of the heat radiating portion 100, as shown in FIG. 3A. Alternatively, the cavity 105 may be formed in both of the upper and intermediate metal layers 102 and 103. However, it is preferable that the cavity 105 is not formed in the lower metal layer 101 such that the LED chip 140 is mounted on the lower metal layer 101.

That is, when the heat radiating portion 100 is composed of three metal layers, the cavity 105 may be formed in the plurality of metal layers such that the top surface of the lowermost metal layer among the metal layers composing the heat radiating portion 100 is exposed through the cavity 105. Alternatively, the cavity 105 may be formed in such a manner that the top surface of two or more metal layers including the lowermost metal layer among the metal layers composing the heat radiating portion 100 are exposed through the cavity 105.

The heat generated when the LED chip 140 mounted in the cavity 105 emits light can be emitted to the outside through the heat radiating portion 100 composed of the metal layers. Therefore, it is preferable that the heat radiating portion 100 is formed of metal with excellent heat conductivity, such as Cu, Ag, Al, Fe, Ni, or W.

Preferably, the inner surface of the cavity 105 is formed of an inclined surface such that light generated from the LED chip 140 can be effectively emitted to the outside.

On the surface of the heat radiating portion 100 including the cavity 105, a reflecting member (not shown) composed of Ag may be additionally formed so as to enhance the reflection efficiency of light emitted from the LED chip 140. The reflecting member may be also formed on the surfaces of the first and second leads 110 and 120.

In the above-described LED package according to the present invention, the LED chip 140 is mounted in the cavity 105 formed in the heat radiating portion 100 composed of metal layers such that most of light generated from the LED chip 140 can be reflected by the inner surface of the cavity 105, not the mold portion 130 formed of resin, so as to be extracted to the outside.

Further, although the inner surface of the cavity 105 is exposed to a high-temperature environment for a long time, the inner surface of the cavity 105 is not easily discolored. Therefore, the brightness of the LED package is prevented from decreasing, which makes it possible to expand the lifespan of the LED package. Further, the LED package can be applied as a high-power package.

Further, the size of a light source is limited depending on the size of the cavity 105 in which the LED chip 140 is mounted. Although the size of the cavity 105 is minimized, it does not have an effect upon the brightness and lifespan of the package. Therefore, it is possible to minimize the size of the light source.

Method of Manufacturing LED Package

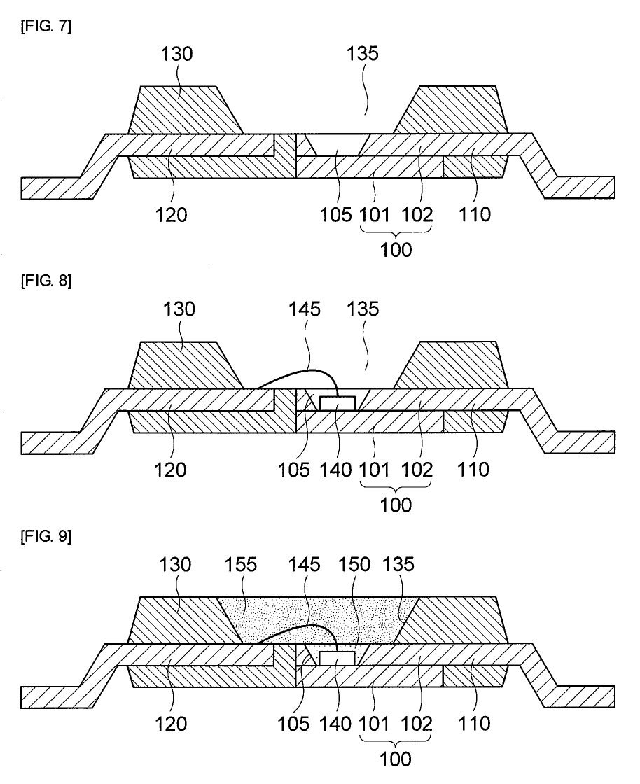

Referring to FIGS. 4 to 10, a method of manufacturing an LED package according to an embodiment of the invention will be described.

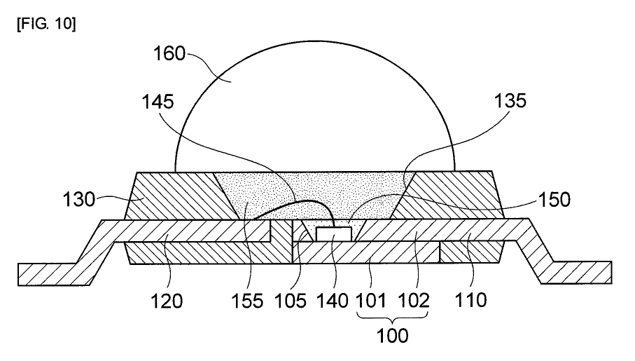

FIGS. 4 and 10 are process diagrams sequentially showing a method of manufacturing an LED package according to an embodiment of the invention.

First, as shown in FIG. 4, a heat radiating portion 100 is provided, which includes a first lead 110 extending from one side of the heat radiating portion 100 and a second lead 120 formed in the other side of the heat radiation portion 100 so as to be separated from the heat radiating portion 100. The heat radiation portion 100 may be formed of one metal plate which is folded in such a manner that two or more layers are provided, as shown in FIGS. 2A and 3A.

Then, as shown in FIG. 5, a cavity 105 is formed in a portion of the heat radiating portion 100. The cavity 105 may be formed by punching or etching. Preferably, the inner surface of the cavity 105 is formed of an inclined surface.

Next, as shown in FIG. 6, the heat radiating portion 100 is folded in such a manner that two metal layers 101 and 102 are provided. In this case, a metal layer having the cavity formed therein is positioned in the uppermost portion.

Then, as shown in FIG. 7, a mold portion 130 is formed so as to integrally fix the heat radiating portion 100 and the first and second leads 110 and 120.

The mold portion 130 composed of resin may be molded by a mold or through pressing. When the mold portion 130 is molded, an opening portion 135 larger than the cavity 105 is formed.

Then, as shown in FIG. 8, an LED chip 140 is mounted in the cavity 105, and the LED chip 140 and the second lead 120 are electrically connected to each other though wire bonding.

Next, as shown in FIG. 9, the cavity 105 is filled with a first filler 150, and the opening portion 135 is filled with a second filler 155. The first and second fillers 150 and 155 may be composed of optically-transparent resin, and the first filler 150 may contain phosphors.

Then, as shown in FIG. 10, a lens 160 is coupled to the top surface of the mold portion 130.

According to the LED package and the method of manufacturing the same, the cavity is formed in the heat radiating portion composed of two or more metal layers, and the LED chip is mounted in the cavity, thereby preventing the degradation of brightness of the LED package. Therefore, the lifespan of the LED package can be enlarged, and the LED package can be applied as a high-power package.

Further, although the size of the cavity is minimized, it does not have an effect upon the brightness and lifespan of the LED package. Therefore, it is possible to minimize the size of a light source.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A light emitting diode (LED) package comprising:
a heat radiating portion that is composed of two or more metal layers and has a cavity formed therein;
a first lead that extends from one side of the heat radiating portion;
a second lead that is formed in the other side of the heat radiating portion so as to be separated from the heat radiating portion;
a mold portion that fixes the heat radiating portion and the first and second leads;
an LED chip that is mounted in the cavity; and
a first filler that is filled in the cavity so as to protect the LED chip,
wherein the mold portion has an opening portion larger than the cavity and a second filler is filled into the opening portion.

2. The LED package according to claim 1, wherein the heat radiating portion is formed of one metal plate which is folded in such a manner that two or more metal layers are provided.

3. The LED package according to claim 1, wherein when the heat radiating portion is composed of two metal layers, the cavity is formed in the upper metal layer of the heat radiating portion.

4. The LED package according to claim 1, wherein when the heat radiating portion is composed of three or more metal layers, the cavity is formed in a plurality of metal layers such that the top surface of the lowermost metal layer of the heat radiating portion is exposed through the cavity.

5. The LED package according to claim 1, wherein when the heat radiating portion is composed of three or more metal layers, the cavity is formed in such a manner that the top surface of two or more metal layers including the lowermost metal layer of the heat radiating portion are exposed through the cavity.

6. The LED package according to claim 1, wherein the inner surface of the cavity is formed of an inclined surface.

7. The LED package according to claim 1 further comprising:
a wire that connects the LED chip and the second lead.

8. The LED package according to claim 1, wherein the mold portion has an opening portion larger than the cavity.

9. The LED package according to claim 8 further comprising:
a second filler that is filled into the opening portion.

10. The LED package according to claim 1 further comprising:
a lens that is coupled to the top surface of the mold portion.

11. The LED package according to claim 1, wherein a reflecting member is formed on the surfaces of the heat radiating portion including the cavity and the first and second leads.

12. The LED package according to claim 11, wherein the reflecting member is formed of Ag.

13. A method of manufacturing an LED package, comprising:
providing a heat radiating portion having a first lead extending from one side of the heat radiating portion and a second lead formed in the other side of the heat radiating portion so as to be separated from the heat radiating portion;
forming a cavity in a portion of the heat radiating portion;
folding the heat radiating portion into two or more metal layers such that the portion in which the cavity is formed is positioned in the uppermost layer;
forming a mold portion which fixes the heat radiating portion and the first and second leads;
mounting an LED chip in the cavity;
connecting the LED chip to the second lead through wire bonding; and
filling the cavity with a first filler.

14. The method according to claim 13, wherein in the forming of the cavity, the inner surface of the cavity is formed of an inclined surface.

15. The method according to claim 13, wherein in the forming of the mold portion, an opening portion larger than the cavity is formed in the mold portion.

16. The method according to claim 13 further comprising:
filling the opening portion with a second filler, after the filling of the cavity.

17. The method according to claim 16 further comprising:
coupling a lens to the top surface of the mold portion, after the filling of the opening portion.

18. A light emitting diode (LED) package comprising:
a heat radiating portion that is formed of one metal plate which is folded in such a manner that two or more metal layers are provided and has a cavity formed therein;
a first lead that extends from one side of the heat radiating portion;
a second lead that is formed in the other side of the heat radiating portion so as to be separated from the heat radiating portion;
a mold portion that fixes the heat radiating portion and the first and second leads, wherein the mold portion has an opening larger than the cavity;
an LED chip that is mounted in the cavity;
a first filler that is filled in the cavity so as to protect the LED chip;
a second filler that is filled into the opening portion,
wherein the first filler may contain one or more kinds of phosphors such that light emitted from a light source provided in a backlight unit is converted into white light and red, green or blue light emitted from the LED chip, depending upon the material forming the LED chip, may be converted into white light by the phosphors contained in the filler so as to be emitted from the package.

19. The LED package according to claim 18,
wherein the first filler and the second filler may be composed of optically transparent resin, such as silicon resin or epoxy resin.

20. The LED package according to claim 18,
wherein on the top surface of the mold portion, a lens is coupled, which extracts light emitted from the LED chip to the outside at a wide orientation angle.

21. The LED package according to claim 18,
wherein the heat radiating portion is formed of metal with excellent heat conductivity, selected from a group consisting of Cu, Ag, Al, Fe, Ni, or W.
